(19) United States
(12) Patent Application Publication
(10) Pub. No.: US 2018/0114854 A1
(43) Pub. Date: Apr. 26, 2018

(54) METAL OXIDE THIN FILM TRANSISTOR AND METHOD OF PREPARING THE SAME

(71) Applicant: Wuhan China Star Optoelectronics Technology Co., Ltd., Wuhan, Hubei (CN)

(72) Inventor: Yingtao XIE, Wuhan (CN)

(21) Appl. No.: 15/115,488

(22) PCT Filed: May 17, 2016
(86) PCT No.: PCT/CN2016/082315

§ 371 Date: Jul. 29, 2016

(30) Foreign Application Priority Data
Mar. 4, 2016 (CN) 201610124804.1

(51) Int. Cl. H01L 29/66; H01L 29/786; H01L 21/467; H01L 21/44; H01L 21/4757

(52) U.S. Cl. CPC H01L 29/66969; H01L 29/7869; H01L 21/467; H01L 27/1225; H01L 21/47573; H01L 29/78603; H01L 21/44

(57) ABSTRACT

A metal oxide thin film transistor and a method of preparing the same, the method includes the following steps: providing a substrate; forming a buffer layer, an oxide film layer, a gate insulating layer and a first metal layer sequentially on the substrate; using a photomask to perform patterning process respectively on the first metal layer, the gate insulating layer and the oxide film layer, to form a gate, a patterned gate insulating layer and an oxide active layer. In the preparation of the film layer structures a method of depositing then etching respectively is adopted, and only one photomask is needed to implement the patterning process on the film layer structures such as the oxide active layer, the gate, and so on.

### TECHNICAL FIELD

The present invention relates to a wafer manufacture field and a display technical field, and in particular to a metal oxide thin film transistor and a method of preparing the same.

### BACKGROUND ART

The thin film transistor liquid crystal panel display is a type of active matrix liquid crystal display apparatus, each liquid crystal pixel on said type of display is driven by a thin film transistor integrated behind the pixel, the thin film transistor (TFT) has significant affect on responsiveness and color fidelity of a display, etc., and is an important component in said type of display. The common thin film transistors mainly include an amorphous silicon thin film transistor (a-Si TFT), a low temperature poly-silicon thin film transistor (LTPS TFT) and a metal oxide thin film transistor, and so on. Wherein a TFT technique of using a metal oxide as a channel layer material has become a highlight of research in the current panel technical field, and especially, a TFT technique using indium gallium zinc oxide (IGZO) can be applied to reduce power consumption of the display screen almost to the level of OLED, a thickness thereof is only 25% more than OLED, also, a resolution may reach a full high definition (full HD, 1920*1080 P) or even an ultra high definition (resolution 4 k*2 k) level, while a cost may become lower.

Currently, the techniques for preparing the metal oxide thin film transistor normally include a back channel etch (BCE) technique, an etch stop layer (ESL) technique and s self-aligned top gate structure. Among the above manufacturing techniques, a photo etching process adopting five masks is relatively common, and at least four masks are needed to complete the manufacturing of the thin film transistor. However, since the cost of the photo etching process is relatively high, if the number of masks used in manufacturing the above array substrate can be reduced, the purpose of simplifying the process flow and reducing the production cost may be achieved.

Based on the above analysis, it can be seen that it is indeed necessary to improve the existing process flow of the metal oxide thin film transistor.

### SUMMARY

In order to overcome the defects of the prior art, the present disclosure aims to provide a metal oxide thin film transistor and a method of preparing the same, which can achieve the purpose of simplifying the process flow and reducing the production cost by optimizing and improving the preparation method of metal oxide thin film transistor.

The present disclosure includes three aspects, and in one aspect, the present disclosure provides a preparing method of a metal oxide thin film transistor, the preparing method comprising:

S1: providing a substrate;

S2: forming a buffer layer, an oxide film layer, a gate insulating layer and a first metal layer sequentially on the substrate;

S3: using a photomask to perform patterning process on the first metal layer, the gate insulating layer and the oxide film layer, patterning the first metal layer to form a gate, patterning the gate insulating layer and patterning the oxide film layer to form an oxide active layer.

[Photoresist] Furthermore, in the preparation method as mentioned in the present disclosure, another step exists after the step S2 and before the step S3: S4: forming a photoresist layer on the first metal layer, and exposing the photoresist layer to obtain the patterned photoresist layer.

[Photoresist-Detail] Furthermore, the step S4 is specifically as follows: depositing the photoresist layer on the first metal layer through spin-coating or printing, and after obtaining the patterned photoresist layer through an exposer, performing a post backing on the patterned photoresist layer.

[Gate-Etching] Furthermore, in the step S3, performing patterning process on the first metal layer is taking the patterned photoresist layer as a barrier, and the first metal layer is etched so as to pattern the first metal layer to form the gate. Wherein a wet etching is performed on the first metal layer.

[Gate Smaller than Photoresist layer] Furthermore, a pattern size of the gate is smaller than a pattern size of the photoresist layer by less than 1 μm.

[Gate Insulating Layer-Etching] Furthermore, in the step S3, performing patterning process on the gate insulating layer is taking the patterned photoresist layer as a barrier, and the gate insulating layer is etched to obtain the patterned gate insulating layer. Wherein a dry etching is performed on the gate insulating layer.

[Oxide Active Layer-Etching] Furthermore, in the step S3, performing patterning process on the oxide film layer is taking the patterned photoresist layer as a barrier, and the oxide film layer is etched so as to pattern the oxide film layer to form the oxide active layer. Wherein a wet etching or a dry etching is performed on the oxide film layer.

[Oxide Active Layer-Material] Furthermore, the oxide film layer is an IGZO film layer. Wherein IGZO refers to Indium Gallium Zinc Oxide.

[Buffer Layer-Material] Furthermore, a material chosen for the buffer layer is SiOₓ.

[Photoresist Removal] Furthermore, in the preparation method as mentioned in the present disclosure, after the step S3, there is another step: S5: removing the patterned photoresist layer.

[Photoresist Removal-Detail] Furthermore, the step S5 is specifically as follows: adopting a plasma-treating technique and using O₂ to ash and remove the photoresist layer.

[Important Dependent Claims: GI, buffer-Dry Etching] Furthermore, in the preparation method as mentioned in the present disclosure, after the step S5, there is another step: S6: etching the patterned gate insulating layer and buffer layer. Wherein the etching performed on the patterned gate insulating layer and the buffer layer is dry etching.

[GI Dry Etching-Detail] Furthermore, etching the gate insulating layer is taking the gate as a protection layer, the gate insulating layer is classified into a first gate insulating layer provided within a gate protection region and a second gate insulating layer exposed outside the gate protection region, the second gate insulating layer is etched away, and the first gate insulating layer is reserved.

[Buffer Dry Etching-Detail] Furthermore, etching the buffer layer is taking the oxide active layer as the protection layer, the buffer layer is classified into a first buffer layer provided within an oxide active layer protection region and a second buffer layer exposed outside the oxide active layer protection region, the second buffer layer is partially or entirely etched away, and the first buffer layer is reserved.

[Buffer Thickness Difference] Furthermore, let a thickness of the first buffer layer be L, and let a thickness of a part etched away of the second buffer layer be d, then 0<d/L≤1. Wherein 0<d/L≤1 refers to values of any points within said value range, for example, d/L=0.2, d/L=0.4, d/L=0.5, d/L=0.6, d/L=0.8.

[S/D] Furthermore, in the preparation method as mentioned in the present disclosure, another step is provided after the step S6: S7: performing a plasma processing on the oxide active layer exposed outside the gate protection region, in order to turn the oxide active layer exposed outside the gate protection region into a conductor to form a source contact region and a drain contact region, so as to facilitate interconnections with the subsequently formed source and drain, which is advantageous in lowering the contact resistance.

Furthermore, the plasma processing may utilize CF₄, NH₃, H₂ or Ar.

[ILD] Furthermore, in the preparation method as mentioned in the present disclosure, there is another step: S8: forming an interlayer dielectric (ILD) on the gate.

Furthermore, the interlayer dielectric is formed through deposition on the gate by using chemical vapor deposition technique, and a material chosen for the interlayer dielectric is one of SiOₓ and SiNₓ or a combination thereof.

[Contact Hole] Furthermore, in the preparation method as mentioned in the present disclosure, there is another step: S9: forming a source contact hole for exposing a part of the source contact region in a region corresponding to the source contact region in the interlayer dielectric; forming a drain contact hole for exposing a part of the drain contact region in a region corresponding to the drain contact region in the interlayer dielectric.

Furthermore, the source contact hole and the drain contact hole are made through photo etching technique.

Furthermore, a second metal layer is deposited in the source contact hole and the drain contact hole, and performing photo etching on the second metal layer to obtain the source and drain respectively; the source contacts the source contact region through the source contact hole; the drain contacts the drain contact region through the drain contact hole.

In another aspect, the present disclosure further provides a metal oxide thin film transistor obtained through the above preparation method, including a substrate, and a buffer layer, an oxide active layer, a gate insulating layer and a gate sequentially provided on the substrate; wherein the gate, the gate insulating layer and the oxide active layer are obtained by performing patterning process respectively on the first metal layer, the gate insulating layer and the oxide film layer formed on the substrate.

[Gate-Etching] Furthermore, performing patterning process on the first metal layer is taking the patterned photoresist layer as a barrier, and the first metal layer is etched so as to pattern the first metal layer to form the gate. Wherein a wet etching is performed on the first metal layer.

[Gate Smaller than Photoresist Layer] Furthermore, a pattern size of the gate is smaller than a pattern size of the photoresist layer.

[Gate Insulating Layer-Etching] Furthermore, performing patterning process on the gate insulating layer is taking the patterned photoresist layer as a barrier, and the gate insulating layer is etched to obtain the patterned gate insulating layer. Wherein a dry etching is performed on the gate insulating layer.

[Oxide Active Layer-Etching] Furthermore, performing patterning process on the oxide film layer is taking the patterned photoresist layer as a barrier, and the oxide film layer is etched so as to pattern the oxide film layer to form the oxide active layer. Wherein a wet etching or a dry etching is performed on the oxide film layer.

[Oxide Active Layer-Material] Furthermore, the oxide active layer is an IGZO film layer. Wherein IGZO refers to Indium Gallium Zinc Oxide.

[Buffer Layer-Material] Furthermore, a material chosen for the buffer layer is SiOₓ.

[Dry Etching-Detail] Furthermore, in the metal oxide thin film transistor as mentioned in the present disclosure, etching the patterned gate insulating layer and the buffer layer. Wherein the etching performed on the patterned gate insulating layer and the buffer layer is dry etching.

[GI Dry Etching-Detail] Furthermore, etching the gate insulating layer is taking the gate as a protection layer, the gate insulating layer is classified into a first gate insulating layer provided within a gate protection region and a second gate insulating layer exposed outside the gate protection region, the second gate insulating layer is etched away, and the first gate insulating layer is reserved.

[Buffer Dry Etching-Detail] Furthermore, etching the buffer layer is taking the oxide active layer as the protection layer, the buffer layer is classified into a first buffer layer provided within an oxide active layer protection region and a second buffer layer exposed outside the oxide active layer protection region, the second buffer layer is partially or entirely etched away, and the first buffer layer is reserved.

[Buffer Thickness Difference] Furthermore, let a thickness of the first buffer layer be L, and let a thickness of a part etched away of the second buffer layer be d, then 0<d/L≤1. Wherein 0<d/L≤1 refers to values of any points within said value range, for example, d/L=0.2, d/L=0.4, d/L=0.5, d/L=0.6, d/L=0.8.

[S/D] Furthermore, in the metal oxide thin film transistor as mentioned in the present disclosure, a source contact region and a drain contact region are further provided, the source contact region and the drain contact region perform a plasma processing on the oxide active layer exposed outside the gate protection region, in order to turn the oxide active layer exposed outside the gate protection region into a conductor.

Furthermore, the plasma processing may utilize CF₄, NH₃, H₂ or Ar.

[ILD] Furthermore, in the metal oxide thin film transistor as mentioned in the present disclosure, an interlayer dielectric is further provided on the gate.

Furthermore, the interlayer dielectric is formed through deposition on the gate by using chemical vapor deposition technique, and a material chosen for the interlayer dielectric is one of SiOₓ and SiNₓ or a combination thereof.

[Contact Hole] Furthermore, in the metal oxide thin film transistor as mentioned in the present disclosure, comprising a source contact hole formed in a region corresponding to the source contact region in the interlayer dielectric and for exposing a part of the source contact region; a drain contact hole for exposing a part of the drain contact region and formed in a region corresponding to the drain contact region in the interlayer dielectric.

Furthermore, the source contact hole and the drain contact hole are made through photo etching technique.

Furthermore, a second metal layer is deposited in the source contact hole and the drain contact hole, and a photo etch is performed on the second metal layer to obtain the source and drain respectively; the source contacts the source contact region through the source contact hole; the drain contacts the drain contact region through the drain contact hole.

In another aspect, the present disclosure further provides a usage of the above metal oxide thin film transistor, and the metal oxide thin film transistor can be used to prepare LCD or OLED display panels.

Compared with the prior art, the advantageous effect of the present disclosure is as follows:

in the traditional thin film transistor preparation method, after forming the oxide film layer, a first photomask is used to perform patterning process on the oxide film layer, so as to form the oxide active layer. Then after forming the first metal layer, a second photomask is used to perform patterning process on the first metal layer, so as to form the gate, thus the above procedure only uses two photomasks. However, in the present disclosure, first, the film layer structures such as the oxide film layer, the first metal layer, and so on are formed sequentially, then only one photomask can be used to perform patterning process on the oxide film layer and the first metal layer, so as to form the oxide active layer and the gate, thereby reducing one photomask, simplifying the process and saving the time, thus reducing the cost effectively. In addition, the present disclosure takes full advantage of the characteristics of wet etching and dry etching, and by adopting different etching techniques on the oxide active layer, the gate and the gate insulating layer respectively, the patterning process can be implemented respectively on the oxide active layer and the gate through a photoetching technique using one photomask.

In addition, the present disclosure discloses forming respective film layers on the substrate, then performing patterning process on the respective film layers, thus after the patterning process, the gate can be directly taken as a protection layer to perform etching on the gate insulating layer and buffer layer parts that are not in the protection region. Through the above procedure, a redundant structure of the gate insulating layer can be etched away, and part of the active layer can be exposed so as to subsequently form the source and drain contact region; meanwhile, the performances of other structures will be not affected, and only a part of the structure of the buffer layer is etched away so as to allow the buffer layer to form a certain stepped difference. The above method can economize the manufacturing procedure, thus reducing the production cost.

### BRIEF DESCRIPTION OF THE DRAWINGS

FIGS. 1-8 illustrate the process of the method for manufacturing metal oxide thin film transistor according to the embodiments of the present disclosure.

### DETAILED DESCRIPTION OF EXEMPLARY EMBODIMENTS

### Embodiments

The present embodiment provides a method of manufacturing a metal oxide thin film transistor, the method comprising:

As shown in FIG. 1, a substrate 1 is provided.

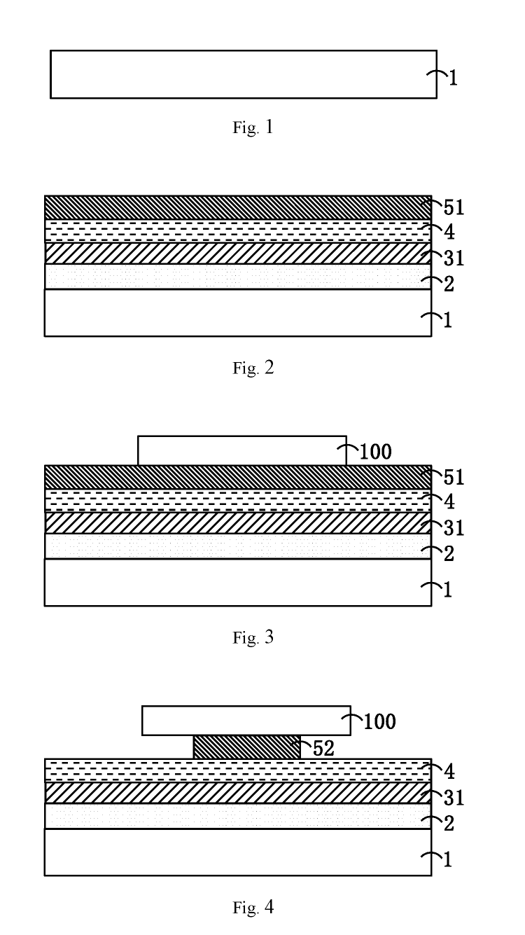

As shown in FIG. 2, a SiOₓ film layer is deposited on the substrate 1 by using the chemical vapor deposition technique, and the SiOₓ film layer is a buffer layer 2; an IGZO oxide film layer 31 is formed on the buffer layer 2 through deposition by using the physical deposition technique; a gate insulating layer 4 is formed on the IGZO oxide film layer 31 through deposition by using the chemical vapor deposition technique; and a first metal layer 51 is formed on the gate insulating layer 4 through deposition by using the physical deposition technique. That is, the buffer layer, the oxide film layer, the gate insulating layer and the first metal layer are sequentially formed on the substrate through deposition by using chemical or physical vapor deposition technique, and after forming the above film layers, the respective film layers are further treated by photoetching and etching.

As shown in FIG. 3, a photoresist layer 100 is formed on the first metal layer 51 through deposition by using spin-coating or printing method, and may be exposed by an exposer to let the photoresist layer to form the needed pattern. The needed pattern at here may refer to pattern formed on the photoresist layer and required when patterning the first metal layer, the IGZO oxide film layer, and so on in the subsequent processes. A post baking should be performed on the patterned photoresist layer 100 to further harden it, in order to prevent deforming of the photoresist layer in the subsequent process.

As shown in FIG. 4, the first metal layer 5 is etched by using the wet etching process, a time duration of the wet etching is controlled to form the patterned first metal layer, that is, a gate 52. Since the wet etching has an isotropic characteristic, it is easy to cause over etch on the gate below the photoresist layer, so as to let a size of the wet etched gate pattern to be smaller than a pattern size of the photoresist layer.

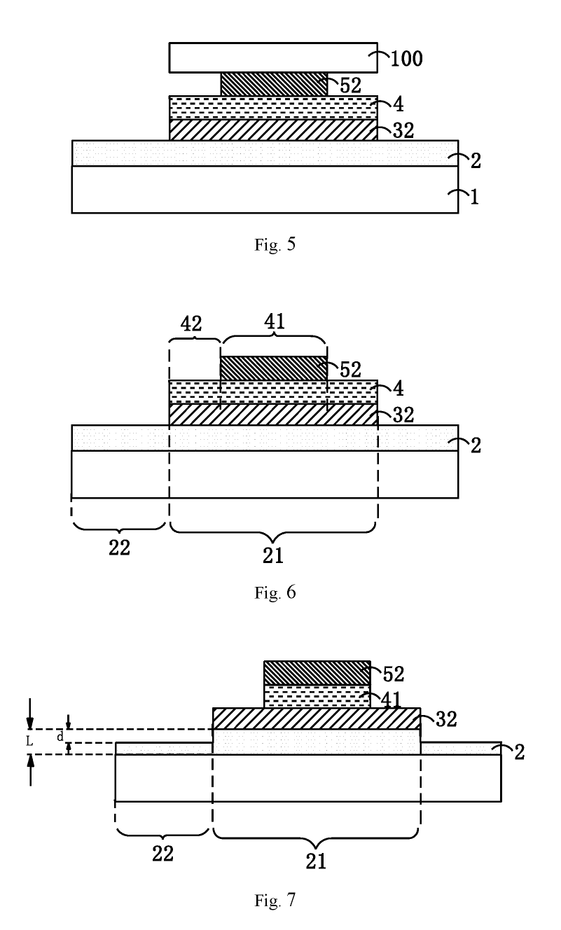

As shown in FIG. 5, the gate insulating layer 4 and the IGZO film layer 31 are etched respectively by using the dry etching process to form the patterned gate insulating layer 4 and patterned IGZO film layer, and the patterned IGZO film layer is the oxide active layer 32. It should be noted that: in this step, a purpose of dry etching the gate insulating layer is: forming a gate insulating layer having a certain pattern.

As shown in FIG. 6, a plasma-treating technique is adopted to ash and remove the photoresist layer 100 by using O₂.

Based on FIG. 6 and FIG. 7, the gate 52 is taken as a protection layer, and a dry etching is performed on the gate insulating layer 4. More particularly, the gate insulating layer 4 below the gate 52 can be classified into a first gate insulating layer 41 provided within a gate protection region and a second gate insulating layer 42 exposed outside the gate protection region. When performing dry etching on the gate insulating layer 4, since the first gate insulating layer 41 is provided within the protection region of the gate 52, it will not be etched away; on the contrary, since the second gate insulating layer 42 is provided outside the protection region of the gate 52, this part of film layer is exposed outside, thus will be etched away during etching. It should be noted that: in this step, a purpose of dry etching the gate insulating layer is: removing redundant gate insulating layer, in order to expose a part of the oxide active layer 32, and said part of exposed oxide active layer 32 will be used to form a source contact region and a drain contact region in the subsequent steps.

Similarly, the oxide active layer 32 is taken as a protection layer to perform dry etching on the buffer layer 2. More particularly, the buffer layer 2 below the oxide active layer can be classified into a first buffer layer 21 provided within an oxide active layer protection region and a second buffer layer 22 exposed outside the oxide active layer protection region. When performing dry etching on the buffer layer 2, since the first buffer layer 21 is provided within the protection region of the oxide active layer 32, it will not be etched away; on the contrary, since the second buffer layer 22 is provided outside the protection region of the oxide active layer 32, this part of film layer is exposed outside, thus a part of the second buffer layer 22 will be etched away during etching. Let a thickness of the first buffer layer be L, and let a thickness of a part etched away of the second buffer layer be d, then d/L=0.5.

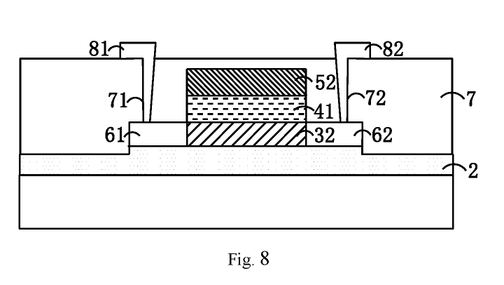

As shown in FIG. 8, the preparation method as mentioned in the present embodiment further comprising: after performing dry etching on the gate insulating layer 4 and the buffer layer 2, performing a plasma processing of CF₄, NH₃, H₂ or Ar on the oxide active layer exposed outside the gate protection region, forming a source contact region 61 on the left of the exposed oxide active layer, and forming a drain contact region 62 on the right; forming an interlayer dielectric 7 made of SiOₓ on the gate 52 through deposition based on the chemical vapor deposition technique, the interlayer dielectric 7 coating the gate 52, the first gate insulating layer 41, the oxide active layer 32, the source contact region 61, the drain contact region 62 and a part of the buffer layer 2 therein; forming a source contact hole 71 for exposing a part of the source contact region 61 in a region corresponding to the source contact region 61 in the interlayer dielectric, and forming a drain contact hole 72 for exposing a part of the drain contact region 62 in a region corresponding to the drain contact region 62 in the interlayer dielectric, by using the photoetching process; forming a second metal layer through deposition on the source contact hole 71, the drain contact hole 72 and the interlayer dielectric, and performing photo etching on the second metal layer to form a source 81 and a drain 82 respectively; the source 81 contacting the source contact region 61 through the source contact hole 71, the drain 82 contacting the drain contact region 62 through the drain contact hole 72.

Furthermore, in the present embodiment, an organic photoresist film may be deposited on the interlayer dielectric by using spin-coating or printing method to form a planarizing layer (not shown) and a post bake is performed on the planarizing layer; in the present embodiment, an ITO film layer may also be deposited and a patterned ITO film layer may be obtained by etching the ITO film layer using the photo etching process, also, ITO film layer may contact the drain.

Understandably, the technique of sequentially forming the film layer structures such as source contact region, the drain contact region, the interlayer dielectric, the source contact hole, the drain contact hole, the source, the drain, the planarizing layer and ITO film layer after performing dry etching on the gate insulating layer and the buffer layer may belong the prior art, and the technical solutions in the above embodiments, or the technical solutions in other prior art may be adopted for these film layers and the techniques for manufacturing the same, which will not be repeated hereby.

In the present embodiment, first, the film layer structures such as the oxide film layer, the first metal layer, and so on are deposited sequentially on the substrate, then, based on the characteristics of wet etching and dry etching, the patterning process is performed respectively on the film layer structures such as the oxide film layer, the first metal layer, and so on, in order to obtain the oxide active layer and the gate. Such operation may achieve the purpose of forming the gate through patterning only by performing photo etching or etching process on the first metal layer by using one photomask after forming the first metal layer, and may achieve the purpose of patterning by performing etching using the same photomask in the subsequent patterning process performed on the oxide film layer. Thus, compared with the existing process, the preparation method as mentioned in the present embodiment can save one photomask, thus saving the time for processing and reducing the production cost.

The present embodiment further provides a metal oxide thin film transistor obtained through the above preparation method, as shown in FIG. 8, including:

a substrate 1;

a buffer layer 2 formed on the substrate 1, the buffer layer 2 having a stepped difference and being made of SiOₓ;

a patterned active layer 32 formed on the buffer layer 2, the oxide active layer being an IGZO film layer, wherein the patterning is obtained by etching the IGZO film layer through the dry etch process;

a source contact region 61 formed on the left of the oxide active layer 32, and a drain contact region 62 formed on the right, wherein the two contact regions are formed by increasing a conductivity of the oxide active layer after processing the oxide active layer through plasma processing technique by using CF₄, NH₃, H₂ or Ar;

a patterned gate insulating layer 4 formed above the oxide active layer 32;

a patterned gate 52 formed on the gate insulating layer 4, wherein the pattern is obtained by etching the first metal layer through the wet etch process;

an interlayer dielectric 7 made of SiOₓ and formed on the gate, wherein the interlayer dielectric 7 coats the gate 52, the gate insulating layer 4, the oxide active layer 32, the source contact region 61, the drain contact region 62 and a part of the buffer layer 2 therein; a source contact hole 71 formed through the photoetching process for exposing a part of the source contact region 61 in a region corresponding to the source contact region 61 in the interlayer dielectric, and a drain contact hole 72 formed through the photoetching process for exposing a part of the drain contact region 62 in a region corresponding to the drain contact region 62 in the interlayer dielectric; a source 81 and a drain 82 forming respectively in the source contact hole 71 and the drain contact hole 72; the source 81 contacts the source contact region 61 through the source contact hole 71, and the drain 82 contacts the drain contact region 62 through the drain contact hole 72.

Wherein the stepped difference of the buffer layer 2 is obtained by using the dry etching process. As shown in FIG. 6, before performing dry etching on the buffer layer 2, the buffer layer 2 below the oxide active layer can be classified into the first buffer layer 21 provided within the oxide active layer protection region and the second buffer layer 22 exposed outside the oxide active layer protection region. When performing dry etching on the buffer layer 2, since the first buffer layer 21 is provided within the protection region of the oxide active layer 32, it will not be etched away; on the contrary, since the second buffer layer 22 is provided outside the protection region of the oxide active layer 32, this part of film layer is exposed outside, thus a part of the second buffer layer 22 will be etched away during etching. Let a thickness of the first buffer layer be L, and let a thickness of a part etched away of the second buffer layer be d, then d/L=0.5.

Wherein the gate insulating layer 4 is obtained by performing the dry etching for twice, in the first dry etching, a patterning process is performed on the gate insulating layer, and in the second dry etching, a redundant part of the gate insulating layer is etched away. Specifically speaking, when performing the second dry etching, as shown in FIG. 6, the gate insulating layer 4 below the gate can be classified into the first gate insulating layer 41 provided within the gate protection region and the second gate insulating layer 42 exposed outside the gate protection region. When performing dry etching on the gate insulating layer 4, since the first gate insulating layer is provided within the protection region of the gate 52, it will not be etched away; on the contrary, since the second gate insulating layer 42 is provided outside the protection region of the gate 52, this part of film layer is exposed outside, thus will be etched away during etching.

In the metal oxide thin film transistor of the present embodiment, an organic photoresist film can be deposited on the interlayer dielectric by using spin-coating or printing to form a planarizing layer (not shown) and a post bake is performed on the planarizing layer; an ITO film layer can also be deposited and a patterned ITO film layer can be obtained by etching the ITO film layer using the photo etching process, also, ITO film layer may contact the drain.

Understandably, the film layer structures such as the source contact region, the drain contact region, the interlayer dielectric, the source contact hole, the drain contact hole, the source, the drain, the planarizing layer, the pixel electrode, and so on all belong to the prior art, and the technical solutions in the above embodiments, or the technical solutions in other prior art may be adopted for these film layers, which will not be repeated hereby.

The above contents only describe the main structure of the metal oxide thin film transistor, while the metal oxide thin film transistor may also include other conventional function structures, which will not be repeated in the present disclosure.

The embodiments of the present disclosure as mentioned above are only the examples made for clearly illustrate the present disclosure, rather than definitions made on the embodiments of the present disclosure. To those skilled in the art, other changes or modifications of different forms can be made based on the above description. Here, it is unnecessary to enumerate all the embodiments. Any modifications, substitutions and improvements made within the spirit and principle of the present disclosure shall fall within the protection scope of the claims of the present disclosure.

1. A preparing method of a metal oxide thin film transistor, wherein the preparing method comprising:
S1: providing a substrate;
S2: forming a buffer layer, an oxide film layer, a gate insulating layer and a first metal layer sequentially on the substrate;
S3: using a photomask to perform patterning process respectively on the first metal layer, the gate insulating layer and the oxide film layer, patterning the first metal layer to form a gate, patterning the gate insulating layer and patterning the oxide film layer to form an oxide active layer.

2. The preparing method according to claim 1, wherein another step is provided after the step S2 and before the step S3: S4: forming a photoresist layer on the first metal layer, and exposing the photoresist layer to obtain the patterned photoresist layer.

3. The preparation method according to claim 2, wherein in the step S3, performing patterning process on the first metal layer is taking the patterned photoresist layer as a barrier, and the first metal layer is etched so as to pattern the first metal layer to form the gate, and a width thereof is smaller than a width of the photoresist layer thereon by more than 1 μm; performing patterning process on the oxide film layer is taking the patterned photoresist layer as a barrier, and performing successive etching on the gate insulating layer and the oxide film layer, so as to pattern the oxide film layer to form the oxide active layer.

4. The preparation method according to claim 2, wherein after the step S3, there is another step: S5: removing the patterned photoresist layer.

5. The preparation method according to claim 2, wherein after the step S5, there is another step: S6: etching the patterned gate insulating layer and the buffer layer.

6. The preparation method according to claim 2, wherein etching the gate insulating layer is taking the gate as a protection layer, the gate insulating layer is classified into a first gate insulating layer provided within a gate protection region and a second gate insulating layer exposed outside the gate protection region, the second gate insulating layer is etched away, and the first gate insulating layer is reserved.

7. The preparation method according to claim 6, wherein etching the buffer layer is taking the oxide active layer as the protection layer, the buffer layer is classified into a first buffer layer provided within an oxide active layer protection region and a second buffer layer exposed outside the oxide active layer protection region, the second buffer layer is partially or entirely etched away, and the first buffer layer is reserved.

8. The preparation method according to claim 6, wherein let a thickness of the first buffer layer be L, and let a thickness of a part etched away of the second buffer layer be d, then 0<d/L≤1.

9. A metal oxide thin film transistor, wherein the metal oxide thin film transistor is manufactured by using the preparation method according to claim 1.

10. A usage of the metal oxide thin film transistor manufactured by using the preparation method according to claim 1, wherein the metal oxide thin film transistor is used to prepare LCD or OLED display panels.
